(19) United States
(12) Patent Application Publication
(10) Pub. No.: US 2026/0305420 A1
(43) Pub. Date: Oct. 1, 2026

(54) METHOD FOR MANUFACTURING MULTILAYER SUBSTRATE, AND SEMICONDUCTOR DEVICE

(71) Applicant: Resonac Corporation, Tokyo (JP)

(72) Inventors: Hirokazu NOMA, Tokyo (JP); Toshiaki SHIRASAKA, Tokyo (JP)

(21) Appl. No.: 19/478,461

(22) PCT Filed: Jun. 7, 2023
(86) PCT No.: PCT/JP2023/021163

§ 371 Date: Oct. 24, 2025

(51) Int. Cl. H10W 70/685; H10W 70/05; H10W 70/695

(52) U.S. Cl. CPC H10W 70/685; H10W 70/095; H10W 70/695

(57) ABSTRACT

As an example of a method for manufacturing a package substrate, first, second, third and fourth substrates 30, 40, 50, 60, each having a cured insulating layer, are prepared. A semi-cured bonding body 70 (prepreg) is sandwiched between the first and second substrates 30, 40 and laminated, then cured to produce a first laminated substrate 100. Similarly, a semi-cured bonding body 80 is sandwiched between the third and fourth substrates 50, 60 and laminated, then cured to produce a second laminated substrate 110. Thereafter, a semi-cured bonding body 90 is sandwiched between the first and second laminated substrates 100, 110 and laminated, then cured to produce a package substrate 1. According to this method, the process can be shortened compared to the case of laminating one layer at a time in sequence, and the shortening effect is particularly remarkable when the number of laminated layers is large.

### TECHNICAL FIELD

The present disclosure relates to a method for manufacturing a multilayer substrate, and particularly to a method for manufacturing a package substrate.

### BACKGROUND ART

Non Patent Literature 1 discloses a method for collectively laminating printed wiring boards. In this method, a core substrate with double-sided copper foil is etched by a subtractive process, and the etched core substrates are stacked with prepregs in between and then heated and pressed to form a laminated board. Thereafter, through-holes are provided in the laminated board, and the walls of the through-holes are copper-plated (through-hole plating) to ensure electrical connection between upper and lower layers. Such a method is used, for example, in the production of motherboards. However, when a substrate is produced by the above-mentioned process, the through-holes penetrate all layers of the substrate, which becomes a constraint when wiring in a planar direction within a single layer. To solve this, a technology called microvias has been developed. In this technology, instead of providing holes that penetrate all layers of the substrate, holes are made in each insulating layer to ensure electrical connection only between the upper and lower layers (see Non Patent Literature 2). Also known is a build-up process in which, after an insulating film is attached, vias are opened by laser processing, and wiring formation is repeated by a semi-additive process (see Non Patent Literature 3). According to this method, a large number of wirings can be formed in a single layer.

Furthermore, with the increasing performance of semiconductor products, the number of input/output terminals required for package substrates is increasing. On the other hand, there is a limit to the number of wirings that can be formed in a single wiring layer. Therefore, efforts are being made to increase the number of build-up layers in package substrates, and increasing the number of build-up layers from nine to twelve is being considered (Non Patent Literature 4). However, the build-up process has a problem in that the production period of the substrate becomes longer in proportion to the number of laminated layers, because the insulating layers are laminated one by one in sequence. As a means to solve this, a multilayer substrate using the PALAP process has been developed (see, for example, Non Patent Literature 5, and Patent Literature 1 and 2). In this method, a plurality of substrates are prepared, in which holes are provided on the side opposite to the copper pattern in a thermoplastic resin with a copper pattern formed on one side, and conductive powder is injected into the holes. Then, a multilayer substrate is produced by collectively laminating the plurality of prepared substrates.

### CITATION LIST

### Patent Literature

Patent Literature 1: Japanese Unexamined Patent Publication No. 2004-146694
Patent Literature 2: Japanese Unexamined Patent Publication No. 2011-187843

### Non Patent Literature

Non Patent Literature 1: Toshiki Sasabe, “History of Printed Wiring Boards”, The Japan Institute of Electronics Packaging, Vol. 16, No. 6 (2013), pp. 428-432
Non Patent Literature 2: Hirotaka Ueda, “Application and Technical Subjects of Conductive Adhesives for Mobile Phone Use”, The Japan Institution of Electronics Packaging, vol. 9, No. 3 (2006), pp. 211-218
Non Patent Literature 3: Michio Horiuchi et al., “Metallization technologies on a smooth resin surface for the next generation of flip chip packaging”, Transactions of The Japan Institute of Electronics Packaging, vol.3, No.1(2010), pp.110-115
Non Patent Literature 4: FC-BGA Substrate, Roadmap, [online], 2022, [searched on Apr. 27, 2023], Internet <URL:https://www.toppan.co.jp/electronics/package/fc-bga/>
Non Patent Literature 5: Yoshitaro Yazaki et al., “Development of PALAP Multilayer Substrate Applying Solid-Phase Diffusion Bonding”, DENSO TECHNICAL REVIEW, vol. 10, No. 2 (2005), pp. 85-89

### SUMMARY OF INVENTION

### Technical Problem

As described above, in the build-up process, since the insulating layers are laminated one by one in sequence, the period for manufacturing the substrate becomes longer in proportion to the number of laminated layers. On the other hand, in the case of a collective lamination process like PALAP, misalignment may occur between each wiring. Therefore, the development of a process that can improve the efficiency of manufacturing a multilayer substrate while suppressing misalignment of each wiring is desired.

An object of the present disclosure is to provide a method for manufacturing a multilayer substrate that can improve the efficiency of manufacturing the multilayer substrate while suppressing misalignment of each wiring.

### Solution to Problem

[1] The present disclosure, as one aspect, relates to a method for manufacturing a multilayer substrate. This method for manufacturing a multilayer substrate includes preparing a first substrate, the first substrate including a first insulating layer, a first wiring provided on a first surface of the first insulating layer, a second wiring provided on a second surface of the first insulating layer, and a first via penetrating the first insulating layer and connecting the first wiring and the second wiring to each other; preparing a second substrate, the second substrate including a second insulating layer, a third wiring provided on a first surface of the second insulating layer, a fourth wiring provided on a second surface of the second insulating layer, and a second via penetrating the second insulating layer and connecting the third wiring and the fourth wiring to each other; preparing a third substrate, the third substrate including a third insulating layer, a fifth wiring provided on a first surface of the third insulating layer, a sixth wiring provided on a second surface of the third insulating layer, and a third via penetrating the third insulating layer and connecting the fifth wiring and the sixth wiring to each other; preparing a first bonding body including a first bonding material and a first connection via penetrating the first bonding material; preparing a second bonding body including a second bonding material and a second connection via penetrating the second bonding material; producing a first laminated substrate by laminating the first substrate and the second substrate such that the first bonding body is sandwiched therebetween; preparing a second laminated substrate including the third substrate; and producing a third laminated substrate by laminating the first laminated substrate and the second laminated substrate such that the second bonding body is sandwiched therebetween.

In this method for manufacturing a multilayer substrate, first, a first laminated substrate is produced by laminating the first substrate and the second substrate such that the first bonding body is sandwiched therebetween, and a second laminated substrate including the third substrate is prepared. Then, a third laminated substrate, which is a multilayer substrate, is produced by laminating the first laminated substrate and the second laminated substrate such that the second bonding body is sandwiched therebetween. In this case, since the number of laminated layers can be increased, for example, by doubling, the period for manufacturing the multilayer substrate can be shortened compared to a process of laminating one layer at a time in sequence. On the other hand, since each laminated substrate is not formed by collectively laminating a large number of substrates, misalignment in each wiring is also less likely to occur. Therefore, according to this method for manufacturing a multilayer substrate, it is possible to improve the efficiency of manufacturing the multilayer substrate while suppressing misalignment of each wiring.

[2] The method for manufacturing a multilayer substrate according to [1] above preferably further includes preparing a fourth substrate, the fourth substrate including a fourth insulating layer, a seventh wiring provided on a first surface of the fourth insulating layer, an eighth wiring provided on a second surface of the fourth insulating layer, and a fourth via penetrating the fourth insulating layer and connecting the seventh wiring and the eighth wiring to each other; and preparing a third bonding body including a third bonding material and a third connection via penetrating the third bonding material. In the preparing the second laminated substrate, it is preferable to produce the second laminated substrate by laminating the third substrate and the fourth substrate such that the third bonding body is sandwiched therebetween. In this case, the period for manufacturing a multilayer substrate having at least eight wiring layers can be further shortened.

[3] In the method for manufacturing a multilayer substrate according to [1] or [2] above, it is preferable that the first insulating layer, the second insulating layer, the third insulating layer, and the fourth insulating layer are insulating layers including a cured curable resin. In this case, the first insulating layer, the second insulating layer, the third insulating layer, and the fourth insulating layer do not melt due to heating in subsequent lamination steps, etc., and misalignment of the wirings provided on each insulating layer is also less likely to occur. Therefore, according to this method for manufacturing a multilayer substrate, misalignment in each wiring can be more reliably suppressed. Note that the curable resin here may be, for example, a thermosetting resin.

[4] In the method for manufacturing a multilayer substrate according to [1] or [2] above, the first insulating layer, the second insulating layer, the third insulating layer, and the fourth insulating layer may be glass substrates. In this case, the first insulating layer, the second insulating layer, the third insulating layer, and the fourth insulating layer do not melt due to heating in subsequent lamination steps, etc., and misalignment of the wirings provided on each insulating layer is also less likely to occur. Therefore, according to this method for manufacturing a multilayer substrate, misalignment in each wiring can be more reliably suppressed.

[5] In the method for manufacturing a multilayer substrate according to any one of [1] to [4] above, it is preferable that the first bonding material is an insulating layer including a semi-cured or uncured curable resin before producing the first laminated substrate, and it is preferable that the second bonding material is an insulating layer including a semi-cured or uncured curable resin before producing the third laminated substrate. In this case, the bonding between the first substrate and the second substrate and the bonding between the first laminated substrate and the second laminated substrate can be performed reliably and easily.

[6] In the method for manufacturing a multilayer substrate according to any one of [1] to [5] above, at least one via among the first via, the second via, and the first connection via may be provided at a position in a planar direction different from other vias. In this case, the design flexibility of the wiring pattern in each wiring can be improved.

[7] In the method for manufacturing a multilayer substrate according to any one of [1] to [6] above, the first connection via may be provided at a position in a planar direction different from the first via and the second via. In this case, the design flexibility of the wiring pattern in each wiring can be improved.

[8] The method for manufacturing a multilayer substrate according to any one of [1] to [7] above may further include preparing a fourth bonding body including a fourth bonding material and a fourth connection via penetrating the fourth bonding material, and in the producing the third laminated substrate, two of the third laminated substrates may be respectively produced by laminating the first laminated substrate and the second laminated substrate such that the second bonding body is sandwiched therebetween. Then, a fourth laminated substrate may be further produced by laminating the two third laminated substrates such that the fourth bonding material is sandwiched therebetween. In this case, a multilayer substrate with a larger number of wiring layers, such as 12 or 16 layers, can be efficiently produced.

[9] The method for manufacturing a multilayer substrate according to any one of [1] to [8] above may further include forming external terminals on an outermost layer of the multilayer substrate. In this case, a multilayer substrate having external terminals can be produced.

[10] In the method for manufacturing a multilayer substrate according to any one of [1] to [9] above, it is preferable that the multilayer substrate to be produced is a package substrate.

[11] The method for manufacturing a multilayer substrate according to any one of [1] to [10] above may further include inspecting at least one substrate among the first substrate, the second substrate, the third substrate, and the fourth substrate before lamination. In this case, by excluding defective substrates or substrates with a high defect rate and advancing non-defective substrates or substrates with a high non-defective rate to the next step, the yield of the multilayer substrate as a whole can be improved.

[12] In the method for manufacturing a multilayer substrate according to any one of [1] to [11] above, in the preparing the first substrate, a plurality of first substrates may be prepared, in the preparing the second substrate, a plurality of second substrates may be prepared, in the producing the first laminated substrate, a plurality of first laminated substrates may be produced, and each of the plurality of first substrates and each of the plurality of second substrates may be a large-format substrate including a plurality of wiring sections. In the inspecting, each wiring section in each of the plurality of first substrates may be inspected, and each wiring section in each of the plurality of second substrates may be inspected. In the producing the first laminated substrate, it is preferable that a combination of each substrate of the plurality of first substrates and each substrate of the plurality of second substrates is selected based on an inspection result in the inspecting. Thereby, by excluding defective substrates or substrates with a high defect rate and advancing non-defective substrates or substrates with a high non-defective rate to the next step, the yield of the multilayer substrate as a whole can be further improved.

[13] In the method for manufacturing a multilayer substrate according to [12] above, in the producing the first laminated substrate, the selection may be performed such that respective wiring sections determined to be non-defective products in the inspecting are superimposed on each other. In this case, the yield of the multilayer substrate can be further improved.

### Advantageous Effects of Invention

According to the present disclosure, it is possible to improve the efficiency of manufacturing a multilayer substrate while suppressing misalignment of each wiring.

### BRIEF DESCRIPTION OF DRAWINGS

FIG. 1 is a cross-sectional view showing an example of a cross-sectional configuration of a package substrate (multilayer substrate) according to an embodiment of the present invention.

(a) and (b) of FIG. 2 are cross-sectional views showing a method for manufacturing the package substrate shown in FIG. 1.

FIG. 3 is a cross-sectional view showing the method for manufacturing the package substrate shown in FIG. 1, and shows a step performed after the steps shown in FIG. 2.

FIG. 4 is a diagram showing another example of a step performed after the steps shown in FIG. 2.

FIG. 5 is a diagram for explaining a step of bonding by reflecting the results of an inspection step.

FIG. 6 is a diagram for explaining a step of bonding by reflecting the results of an inspection step.

FIG. 7 is a perspective view for explaining the bonding step of FIG. 5 and FIG. 6.

FIG. 8 is a diagram for explaining a step of bonding as is without reflecting the results of an inspection step when there are a plurality of substrates.

FIG. 9 is a diagram for explaining a step of performing a selection process by reflecting the results of an inspection step and then bonding when there are a plurality of substrates.

### DESCRIPTION OF EMBODIMENTS

Hereinafter, embodiments according to the present invention will be described in detail with reference to the drawings. In the following description, the same or corresponding parts are denoted by the same reference numerals, and redundant descriptions will be omitted. In addition, positional relationships such as up, down, left, and right are based on the positional relationships shown in the drawings unless otherwise specified. Furthermore, the dimensional ratios in the drawings are not limited to the illustrated ratios.

In this specification, the term “layer” includes not only a structure with a shape formed over the entire surface when observed as a plan view, but also a structure with a shape formed in a part. In this specification, the term “step” is not limited to an independent step, but is included in this term as long as the intended action of the step is achieved, even if it cannot be clearly distinguished from other steps.

In this specification, a numerical range indicated using “to” indicates a range including the numerical values described before and after “to” as the minimum value and the maximum value, respectively. In a numerical range described in stages in this specification, the upper limit value or the lower limit value of a numerical range of one stage may be replaced with the upper limit value or the lower limit value of a numerical range of another stage. In a numerical range described in this specification, the upper limit value or the lower limit value of the numerical range may be replaced with a value shown in an example.

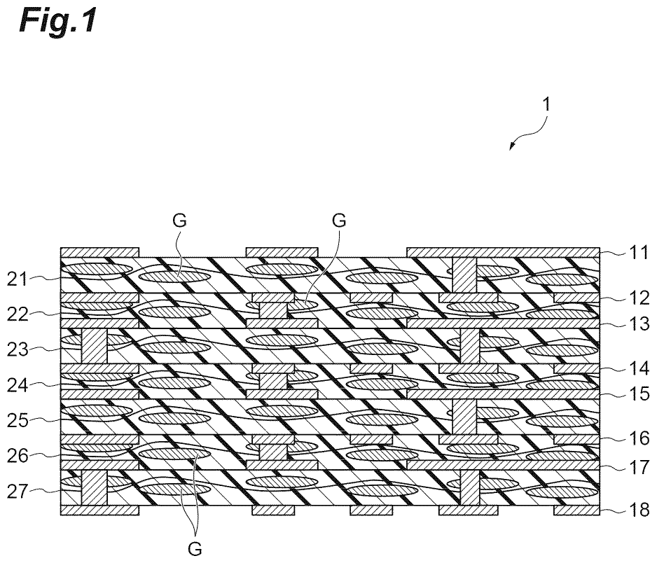

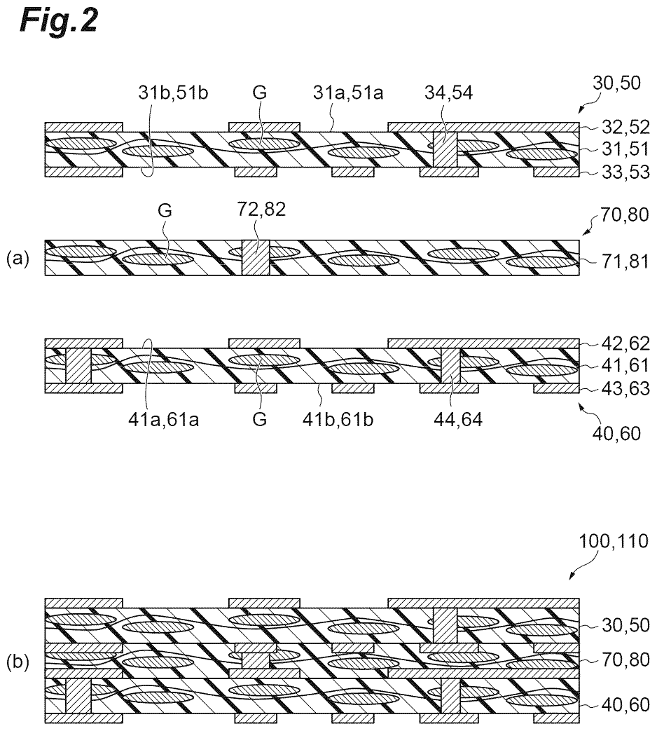

FIG. 1 is a diagram showing an example of a package substrate manufactured by a manufacturing method according to an embodiment of the present invention. As shown in FIG. 1, a package substrate 1 (multilayer substrate, third laminated substrate) is a substrate including eight wiring layers. The package substrate 1 includes a first wiring layer 11, a second wiring layer 12, a third wiring layer 13, a fourth wiring layer 14, a fifth wiring layer 15, a sixth wiring layer 16, a seventh wiring layer 17, an eighth wiring layer 18, a first insulating layer 21, a second insulating layer 22, a third insulating layer 23, a fourth insulating layer 24, a fifth insulating layer 25, a sixth insulating layer 26, and a seventh insulating layer 27. Each wiring layer from the first wiring layer 11 to the eighth wiring layer 18 can be formed, for example, by a subtractive method or a semi-additive method. Other methods may also be used. The first wiring layer 11 to the eighth wiring layer 18 are formed, for example, from a metal such as copper. The thickness of the first wiring layer 11 to the eighth wiring layer 18 is, for example, 5 μm to 35 μm, and preferably 9 μm to 25 μm.

The first insulating layer 21 to the seventh insulating layer 27 are formed, for example, including a curable resin such as a thermosetting resin, and are in a state of a cured product of the curable resin in the state of the package substrate 1. The first insulating layer 21 to the seventh insulating layer 27 may have a configuration that includes a glass cloth G in the curable resin, or may have a configuration that does not include the glass cloth G. The first insulating layer 21 to the seventh insulating layer 27 are, for example, cured products of prepreg. The first insulating layer 21 to the seventh insulating layer 27 may be formed from a glass substrate. By arranging each of such first insulating layer 21 to seventh insulating layer 27 between each of the first wiring layer 11 to the eighth wiring layer 18, insulation between the wiring layers is ensured. On the other hand, the first insulating layer 21 to the seventh insulating layer 27 may be provided with vias (microvias) penetrating each insulating layer, and such vias are configured to allow necessary electrical connection between the wiring layers. Such a package substrate 1 may be, for example, a package substrate for FC-BGA. Note that although the package substrate 1 shown in FIG. 1 includes eight wiring layers (first wiring layer 11 to eighth wiring layer 18), it is not limited to this, and may include six wiring layers, twelve wiring layers, sixteen wiring layers, or twenty-four wiring layers.

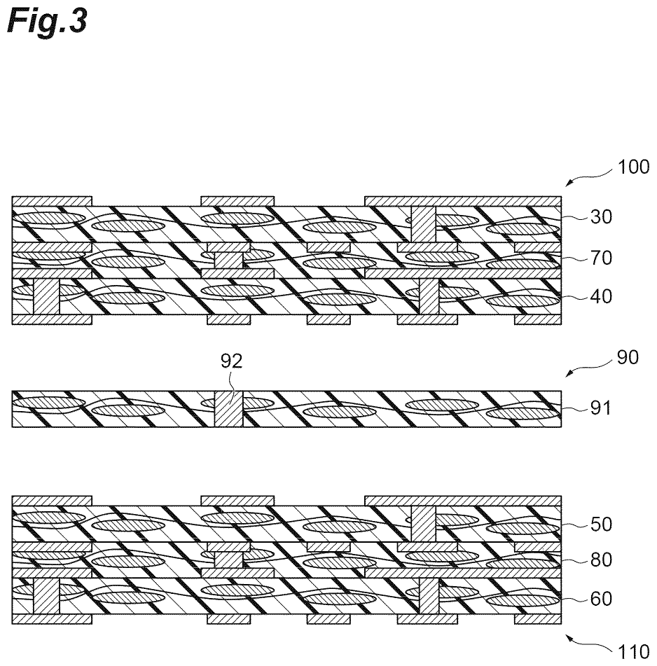

Next, a method for manufacturing the package substrate 1 will be described with reference to FIG. 2 and FIG. 3. (a) and (b) of FIG. 2 are cross-sectional views showing a method for manufacturing the package substrate shown in FIG. 1. FIG. 3 is a cross-sectional view showing the method for manufacturing the package substrate shown in FIG. 1, and shows a step performed after the steps shown in FIG. 2. This manufacturing method includes the following steps [A] to [J].
Step A: A step of preparing a first substrate, the first substrate including a first insulating layer, a first wiring provided on a first surface of the first insulating layer, a second wiring provided on a second surface of the first insulating layer, and a first via penetrating the first insulating layer and connecting the first wiring and the second wiring to each other.
Step B: A step of preparing a second substrate, the second substrate including a second insulating layer, a third wiring provided on a first surface of the second insulating layer, a fourth wiring provided on a second surface of the second insulating layer, and a second via penetrating the second insulating layer and connecting the third wiring and the fourth wiring to each other.
Step C: A step of preparing a third substrate, the third substrate including a third insulating layer, a fifth wiring provided on a first surface of the third insulating layer, a sixth wiring provided on a second surface of the third insulating layer, and a third via penetrating the third insulating layer and connecting the fifth wiring and the sixth wiring to each other.
Step D: A step of preparing a fourth substrate, the fourth substrate including a fourth insulating layer, a seventh wiring provided on a first surface of the fourth insulating layer, an eighth wiring provided on a second surface of the fourth insulating layer, and a fourth via penetrating the fourth insulating layer and connecting the seventh wiring and the eighth wiring to each other.
Step E: A step of preparing a first bonding body including a first bonding material and a first connection via penetrating the first bonding material.
Step F: A step of preparing a third bonding body including a third bonding material and a third connection via penetrating the third bonding material.
Step G: A step of preparing a second bonding body including a second bonding material and a second connection via penetrating the second bonding material.
Step H: A step of producing a first laminated substrate by laminating the first substrate and the second substrate such that the first bonding body is sandwiched therebetween.
Step I: A step of producing a second laminated substrate by laminating the third substrate and the fourth substrate such that the third bonding body is sandwiched therebetween.
Step J: A step of producing a multilayer substrate by laminating the first laminated substrate and the second laminated substrate such that the second bonding body is sandwiched therebetween.

### Step A

In step A, as shown in (a) of FIG. 2, a first substrate 30 is prepared. The first substrate 30 has an insulating layer 31 (first insulating layer), a wiring layer 32 (first wiring) provided on a first surface 31a of the insulating layer 31, a wiring layer 33 (second wiring) provided on a second surface 31b of the insulating layer 31, and a via 34 (first via) penetrating the insulating layer 31 and connecting the wiring layer 32 and the wiring layer 33 to each other.

The insulating layer 31 is configured to include a thermosetting resin such as an epoxy resin, and is formed, for example, from a prepreg including a glass cloth G. The resin composition constituting the insulating layer 31 may include a phenol resin compound, an acid anhydride compound, an amine compound, or a hydrazide compound as a curing agent. The insulating layer 31 is a cured product (so-called C-stage) in which a prepreg or the like has been cured. The insulating layer 31, in a cured state, has a thickness of, for example, 7 μm to 100 μm, and preferably 20 μm to 60 μm. Note that the insulating layer 31 may be a glass substrate.

A wiring layer 32 is formed on the first surface 31a of the insulating layer 31. Also, a wiring layer 33 is formed on the second surface 31b of the insulating layer 31. The wiring layers 32, 33 are wirings made of a metal such as copper, gold, or silver, and can be formed on the insulating layer 31 by a subtractive method or a semi-additive method. They may be formed by other methods. The wiring layers 32, 33 may be a metal plating layer, a metal foil such as a copper foil, a layer formed by vapor deposition such as sputtering, or a metal sintered layer. The thickness of the wiring layers 32, 33 may be, for example, 5 μm to 35 μm. The insulating layer 31 may further be formed with a via 34 that penetrates the insulating layer 31 in the lamination direction and connects the wiring layer 32 and the wiring layer 33 to each other. The via 34 is formed, for example, from a metal such as copper.

### Step B

In step B, a second substrate 40 is prepared. The second substrate 40 has a configuration similar to that of the first substrate 30, and has an insulating layer 41 (second insulating layer), a wiring layer 42 (third wiring) provided on a first surface 41a of the insulating layer 41, a wiring layer 43 (fourth wiring) provided on a second surface 41b of the insulating layer 41, and a via 44 (second via) penetrating the insulating layer 41 and connecting the wiring layer 42 and the wiring layer 43 to each other. Since the materials and formation methods of the insulating layer 41 and the wiring layers 42, 43 of the second substrate 40 are the same as those of the first substrate 30, a detailed description is omitted.

### Step C

In step C, a third substrate 50 is prepared. The third substrate 50 has a configuration similar to that of the first substrate 30, and has an insulating layer 51 (third insulating layer), a wiring layer 52 (fifth wiring) provided on a first surface 51a of the insulating layer 51, a wiring layer 53 (sixth wiring) provided on a second surface 51b of the insulating layer 51, and a via 54 (third via) penetrating the insulating layer 51 and connecting the wiring layer 52 and the wiring layer 53 to each other. Since the materials and formation methods of the insulating layer 51 and the wiring layers 52, 53 of the third substrate 50 are the same as those of the first substrate 30, a detailed description is omitted.

### Step D

In step D, a fourth substrate 60 is prepared. The fourth substrate 60 has a configuration similar to that of the first substrate 30, and has an insulating layer 61 (fourth insulating layer), a wiring layer 62 (seventh wiring) provided on a first surface 61a of the insulating layer 61, a wiring layer 63 (eighth wiring) provided on a second surface 61b of the insulating layer 61, and a via 64 (fourth via) penetrating the insulating layer 61 and connecting the wiring layer 62 and the wiring layer 63 to each other. Since the materials and formation methods of the insulating layer 61 and the wiring layers 62, 63 of the fourth substrate 60 are the same as those of the first substrate 30, a detailed description is omitted.

### Step E

In step E, a bonding body 70 (first bonding body) is prepared. The bonding body 70 has a bonding material 71 (first bonding material) and a connection via 72 (first connection via) penetrating the bonding material 71. The bonding material 71 of the bonding body 70 is a member for bonding the first substrate 10 and the second substrate 20, and is, for example, in a semi-cured (B-stage) or uncured state of a curable resin such as a thermosetting resin, and is configured from a prepreg or the like including a glass cloth G. The bonding material 71 is formed from a resin or the like and has insulating properties. This bonding material 71 is provided with a connection via 72 that penetrates the bonding material 71. The connection via 72 is formed, for example, from a metal such as copper. The bonding material 71 is preferably configured from the same prepreg as the insulating layers 31, 41, 51, 61, but since the bonding material 71 is a member for bonding, it differs in that it is in a semi-cured or uncured state before bonding (before step H described later).

### Step F

In step F, a bonding body 80 (third bonding body) is prepared. The bonding body 80, similarly to the bonding body 70, has a bonding material 81 (third bonding material) and a connection via 82 (third connection via) penetrating the bonding material 81. Since the materials and formation methods of the bonding material 81 (insulating layer) and the connection via 82 of the bonding body 80 are the same as those of the bonding body 70, a detailed description is omitted.

### Step G

In step G, a bonding body 90 (second bonding body) is prepared (see FIG. 3). The bonding body 90, similarly to the bonding body 70, has a bonding material 91 (second bonding material) and a connection via 92 (second connection via) penetrating the bonding material 91. Since the materials and formation methods of the bonding material 91 (insulating layer) and the connection via 92 of the bonding body 90 are the same as those of the bonding body 70, a detailed description is omitted.

### Step H

In step H, as shown in (a) and (b) of FIG. 2, when the preparation of the first substrate 30, the second substrate 40, and the bonding body 70 is completed, the first substrate 30 and the second substrate 40 are laminated such that the bonding body 70 is sandwiched between the first substrate 30 and the second substrate 40 to produce a first laminated substrate 100. That is, the semi-cured or uncured bonding body 70 is sandwiched between the first substrate 30 and the second substrate 40 to function as an adhesive, and the first substrate 30 and the second substrate 40 are bonded to form a laminated body. Thereafter, the laminated body is subjected to heating and pressing to cure the semi-cured or uncured bonding body 70, thereby producing the first laminated substrate 100. The temperature for curing is, for example, 100 °C to 250 °C, and the pressure during pressing is 0.2 to 10 MPa. Note that since the insulating layers 31, 41 of the first substrate 30 and the second substrate 40 are cured products of a curable resin or glass substrates, even if heated in step H, the wiring layers 32, 33, the wiring layers 42, 43, and the vias 34, 44 will not be displaced from their initial positions.

### Step I

In step I, when the preparation of the third substrate 50, the fourth substrate 60, and the bonding body 80 is completed, the third substrate 50 and the fourth substrate 60 are laminated such that the bonding body 80 is sandwiched between the third substrate 50 and the fourth substrate 60 to produce a second laminated substrate 110. That is, similarly to the first laminated substrate 100, the semi-cured or uncured bonding body 80 is sandwiched between the third substrate 50 and the fourth substrate 60 to function as an adhesive, and the third substrate 50 and the fourth substrate 60 are bonded to form a laminated body. Thereafter, the laminated body is subjected to heating and pressing to cure the semi-cured or uncured bonding body 80, thereby producing the second laminated substrate 110. The temperature and pressure for curing are the same as in the case of producing the first laminated substrate 100. Note that since the insulating layers 51, 61 of the third substrate 50 and the fourth substrate 60 are cured products of a curable resin or glass substrates, even if heated in step I, the wiring layers 52, 53, the wiring layers 62, 63, and the vias 54, 64 will not be displaced from their initial positions.

### Step J

In step J, as shown in FIG. 3, when the preparation of the first laminated substrate 100, the second laminated substrate 110, and the bonding body 90 is completed, the first laminated substrate 100 and the second laminated substrate 110 are laminated such that the bonding body 90 is sandwiched between the first laminated substrate 100 and the second laminated substrate 110 to produce the package substrate 1. That is, the semi-cured or uncured bonding body 90 is sandwiched between the first laminated substrate 100 and the second laminated substrate 110 to function as an adhesive, and the first laminated substrate 100 and the second laminated substrate 110 are bonded to form a laminated body. Thereafter, the laminated body is subjected to heating and pressing to cure the semi-cured or uncured bonding body 90, thereby producing the package substrate 1 (see FIG. 1). The temperature and pressure for curing are the same as in the case of producing the first laminated substrate 100, etc. Note that since each insulating layer of the first laminated substrate 100 and the second laminated substrate 110 is a cured product of a curable resin or a glass substrate, even if reheated in step J, the wiring layers 32, 33, the wiring layers 42, 43, the wiring layers 52, 53, the wiring layers 62, 63, and the vias 34, 44, 54, 64 will not be displaced from their initial positions.

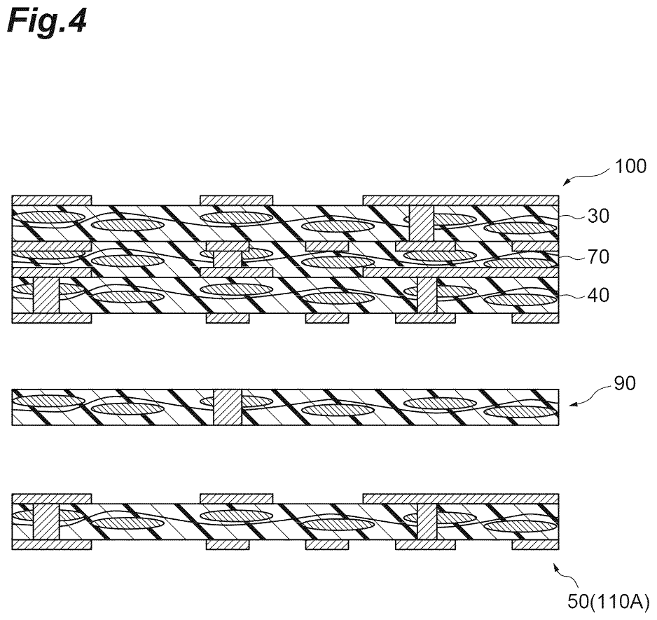

In this way, laminated substrates each having four wiring layers are bonded to form eight wiring layers. However, as shown in FIG. 4, a laminated body may be formed by sandwiching a semi-cured or uncured bonding body 90 between a first laminated substrate 100, which is a laminated substrate having four wiring layers, and a third substrate 50 having two wiring layers, to function as an adhesive, and bonding the first laminated substrate 100 and a second laminated substrate 110A including the third substrate 50. In this case, thereafter, the laminated body can be subjected to heating and pressing to cure the semi-cured or uncured bonding body 90, thereby producing a six-layer package substrate.

Note that external terminals may be formed on the outermost layer of the package substrate 1, which is a multilayer substrate after laminating and curing the first laminated substrate 100 and the second laminated substrate 110. This produces a package substrate having external terminals. Furthermore, it is possible to produce a semiconductor device by mounting a semiconductor element on the package substrate manufactured in this way.

As described above, in the method for manufacturing a package substrate according to the present embodiment, first, a first laminated substrate 100 is produced by laminating the first substrate 30 and the second substrate 40 such that the bonding body 70 is sandwiched therebetween, and second laminated substrate 110 or 110A is produced by laminating the third substrate 50 and the fourth substrate 60 such that the bonding body 80 is sandwiched therebetween, or so as to include the third substrate 50. Then, the package substrate 1 is produced by laminating the first laminated substrate 100 and the second laminated substrate 110 or 110A such that the bonding body 90 is sandwiched therebetween. In this case, since the number of laminated layers can be increased by doubling, the period for manufacturing the package substrate 1 can be shortened compared to a process of laminating one layer at a time. On the other hand, since each laminated substrate is not one in which a large number of substrates are laminated, misalignment in each wiring layer is also less likely to occur. Therefore, according to this method for manufacturing a package substrate, it is possible to improve the efficiency of manufacturing a package substrate, which is a multilayer substrate, while suppressing misalignment of each wiring layer.

Furthermore, in the method for manufacturing a package substrate according to the present embodiment, it is preferable that the insulating layers 31, 41, 51, 61 are insulating layers including a cured thermosetting resin. In this case, each insulating layer is not melted by heating in subsequent lamination steps, etc., and misalignment of each wiring layer is also less likely to occur. Therefore, according to this method for manufacturing a package substrate, misalignment in each wiring layer can be more reliably suppressed.

Furthermore, in the method for manufacturing a package substrate according to the present embodiment, the insulating layers 31, 41, 51, 61 may be glass substrates. In this case, each insulating layer is not melted by heating in subsequent lamination steps, etc., and misalignment of each wiring layer is also less likely to occur. Therefore, according to this method for manufacturing a package substrate, misalignment in each wiring layer can be more reliably suppressed.

Furthermore, in the method for manufacturing a package substrate according to the present embodiment, it is preferable that the bonding body 70 is an insulating layer including a semi-cured or uncured thermosetting resin before producing the first laminated substrate 100. It is preferable that the bonding body 80 is an insulating layer including a semi-cured or uncured thermosetting resin before producing the second laminated substrate 110. In this case, the bonding between the first substrate 30 and the second substrate 40, and the bonding between the third substrate 50 and the fourth substrate 60 can be performed reliably and easily. Furthermore, it is preferable that the bonding body 90 is an insulating layer including a semi-cured or uncured thermosetting resin before producing the package substrate 1. In this case, the bonding between the first laminated substrate 100 and the second laminated substrate 110 can be performed reliably and easily.

Furthermore, in the method for manufacturing a package substrate according to the present embodiment, the connection vias 72, 82 may be provided at positions in a planar direction different from the vias 34, 54 and the vias 44, 64. In this case, the design flexibility of the wiring pattern in each wiring layer can be improved.

Note that, as shown in FIG. 3, two package substrates 1, which are third laminated substrates each obtained by bonding and curing the first laminated substrate 100 and the second laminated substrate 110 with the bonding body 90, may be produced, and another bonding body (fourth bonding body) having a configuration similar to that of the bonding body 90 may be laminated so as to be sandwiched between the two package substrates 1 (third laminated substrates) and cured them to produce a package substrate (fourth laminated substrate) having 16 wiring layers. This other bonding body, similarly to the bonding body 90, has a bonding material (fourth bonding material) and a connection via (fourth connection via) penetrating this bonding material. When such production is performed, a package substrate with a larger number of layers, such as 16 layers, can be efficiently produced.

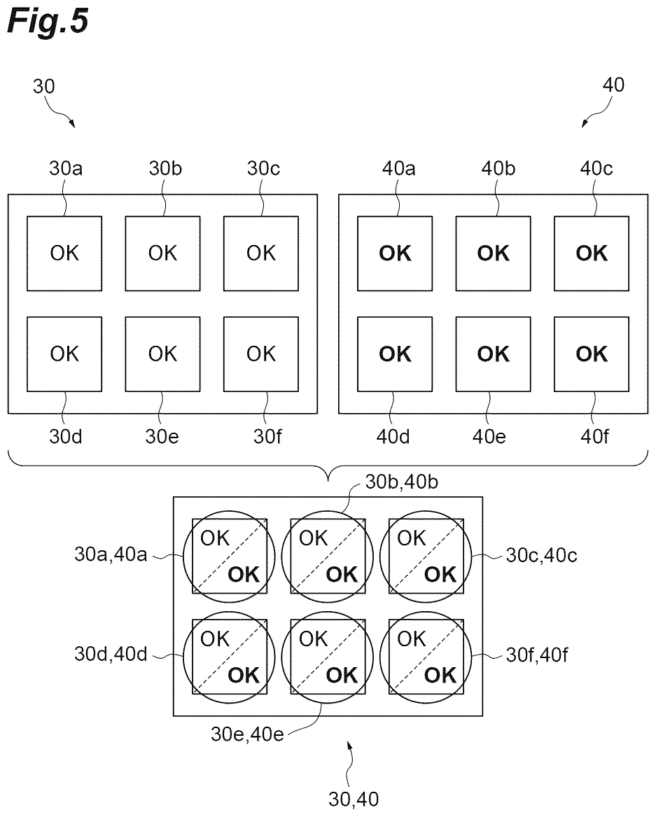

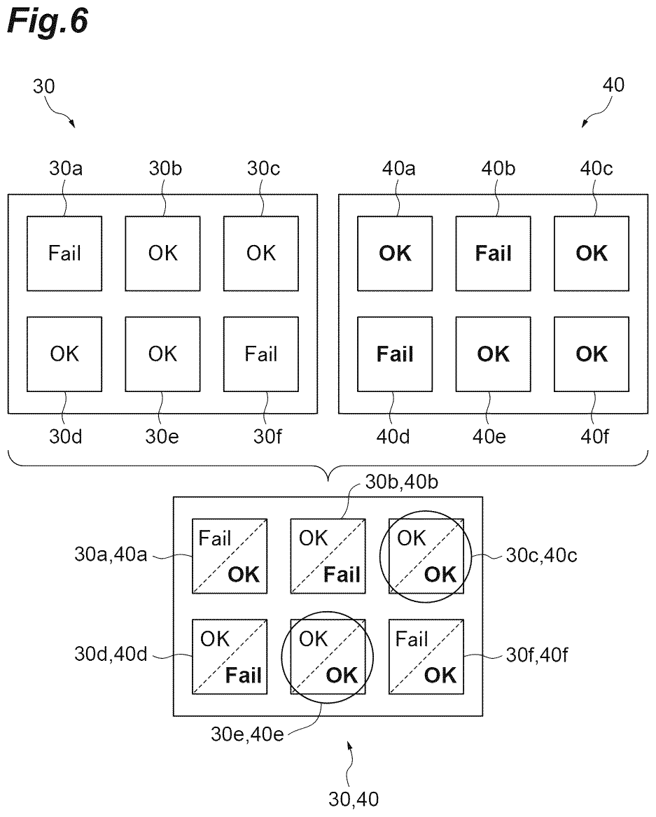

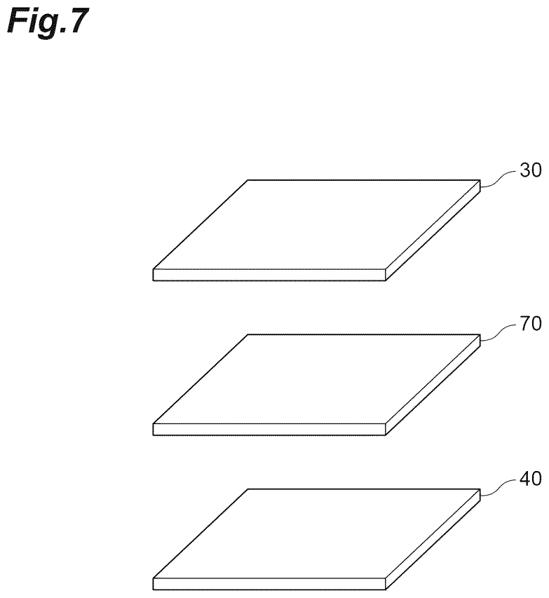

Although the embodiments of the present disclosure have been described above, the present invention is not limited to the above-described embodiments, and appropriate changes may be made without departing from the spirit thereof. For example, in the above-described method for manufacturing a package substrate, units of laminated substrates are bonded together. For this reason, in the method for manufacturing a package substrate according to the present embodiment, before producing a laminated body (for example, before laminating the first substrate 30 and the second substrate 40 as shown in FIG. 7), a continuity test may be performed on the wiring sections 30a to 30f and 40a to 40f included in each substrate, as shown in FIG. 5 and FIG. 6. In this case, each substrate is a large-format substrate including a plurality of wiring sections, and the continuity test is performed by inspecting the continuity and insulation of each wiring section from both sides of the substrate with a flying probe or the like. As a result of the continuity test, if there is a wiring section determined to be defective (Fail) (see FIG. 6), by not manufacturing that part or not using that substrate, the overall yield can be improved. FIG. 5 shows a case where all wiring sections are non-defective (OK), and FIG. 6 shows a case where some wiring sections are defective (Fail). In the example of FIG. 6, for example, the wiring sections 30c, 40c and the wiring sections 30e, 40e where non-defective products (OK) overlap are used as subsequent products, and since it is clear that the other wiring sections are defective (Fail), subsequent inspections can be omitted.

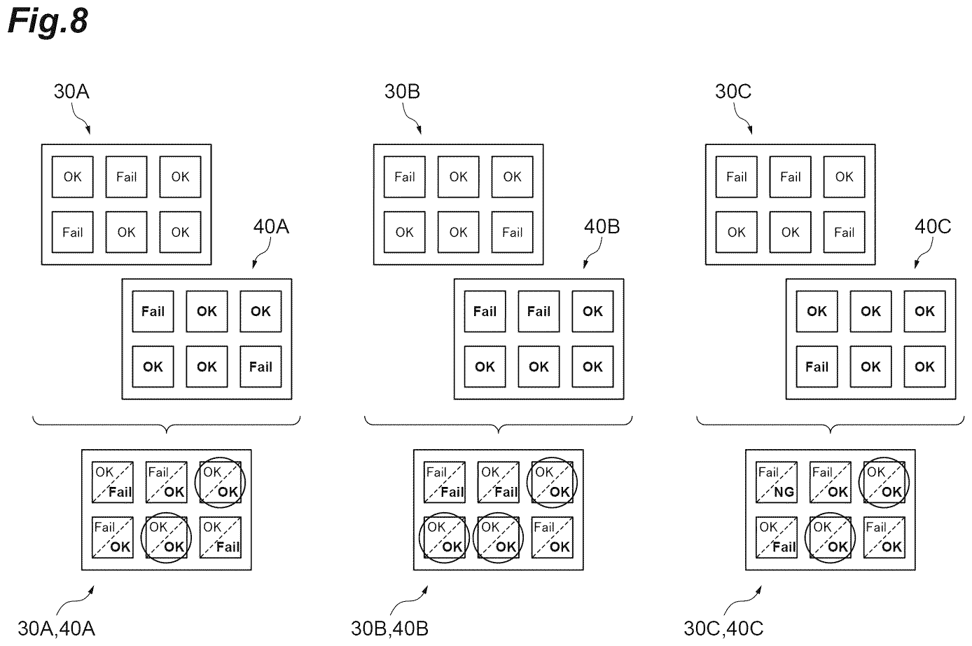

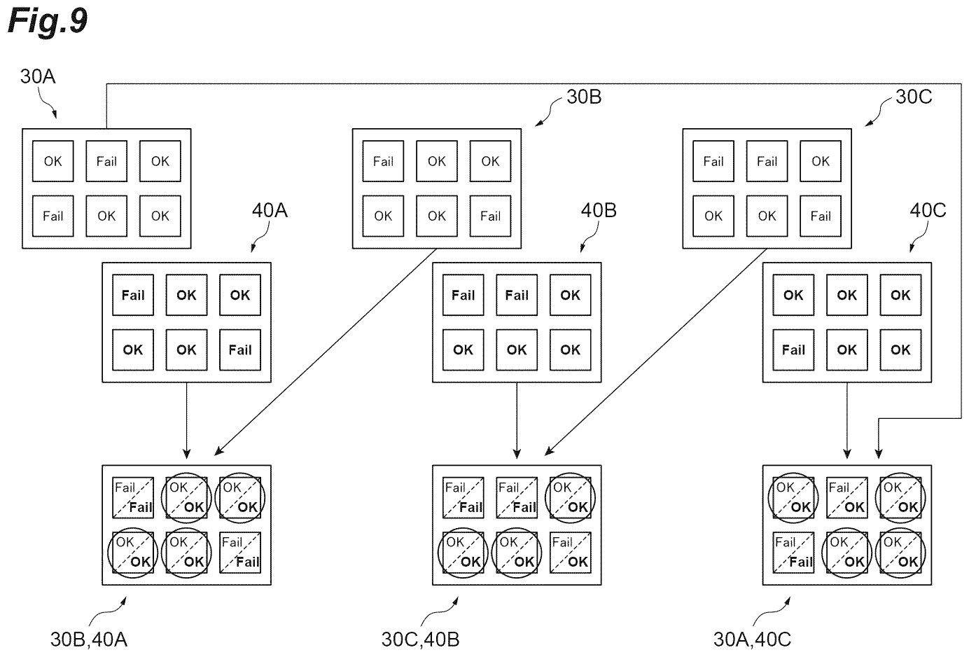

Furthermore, when producing a plurality of first substrates 30A, 30B, 30C and a plurality of second substrates 40A, 40B, 40C, as shown in FIG. 8, each wiring section in each of the plurality of first substrates 30A to 30C may be inspected (determined as OK or Fail), and each wiring section in each of the plurality of second substrates 40A to 40C may also be inspected (determined as OK or Fail). Then, as shown in FIG. 8, the corresponding first substrate 30A and second substrate 40A, the corresponding first substrate 30B and second substrate 40B, and the corresponding first substrate 30C and second substrate 40C may be bonded with each bonding body 70. In this case, for example, the number of overlapping non-defective wiring sections is seven. On the other hand, based on the inspection results of each wiring section in the plurality of first substrates 30A to 30C and the inspection results of each wiring section in the plurality of second substrates 40A to 40C, as shown in FIG. 9, a selection process may be performed such that more wiring sections determined to be non-defective are superimposed, and the first substrate and the second substrate may be bonded. In this case, for example, as shown in FIG. 9, the number of overlapping non-defective wiring sections (overlapping OKs) becomes eleven. Such a selection process may be performed by calculating the yield of all combinations of substrates using a computer, or other processing methods may be used.

Note that in the above-described inspection step and non-defective product selection step, the case of bonding the first substrate 30 and the second substrate 40 was described as an example, but the present invention is not limited to this, and it may of course be applied when bonding the third substrate 50 and the fourth substrate 60, or when bonding the first laminated substrate 100 and the second laminated substrate 110 or 110A. By performing such inspection and selection steps, the yield can be reliably improved compared to the case of collectively laminating insulating layers.

Furthermore, in the above-described embodiments, the case of producing a package substrate was described as an example, but it is of course possible to apply the present invention to the case of producing other multilayer substrates.

### REFERENCE SIGNS LIST

1 . . . package substrate (multilayer substrate, third laminated substrate), 30, 30A to 30C . . . first substrate, 31 . . . insulating layer (first insulating layer), 32 . . . wiring layer (first wiring), 33 . . . wiring layer (second wiring), 34 . . . via (first via), 40, 40A to 40C . . . second substrate, 41 . . . insulating layer (second insulating layer), 42 . . . wiring layer (third wiring), 43 . . . wiring layer (fourth wiring), 44 . . . via (second via), 50 . . . third substrate, 51 . . . insulating layer (third insulating layer), 52 . . . wiring layer (fifth wiring), 53 . . . wiring layer (sixth wiring), 54 . . . via (third via), 60 . . . fourth substrate, 61 . . . insulating layer (fourth insulating layer), 62 . . . wiring layer (seventh wiring), 63 . . . wiring layer (eighth wiring), 64 . . . via (fourth via), 70 . . . bonding body (first bonding body), 71 . . . bonding material (first bonding material), 72 . . . connection via (first connection via), 80 . . . bonding body (third bonding body), 81 . . . bonding material (third bonding material), 82 . . . connection via (third connection via), 90 . . . bonding body (second bonding body), 91 . . . bonding material (second bonding material), 92 . . . connection via (second connection via), 100 . . . first laminated substrate, 110, 110A . . . second laminated substrate.

1. A method for manufacturing a multilayer substrate, comprising:
preparing a first substrate, the first substrate comprising a first insulating layer, a first wiring provided on a first surface of the first insulating layer, a second wiring provided on a second surface of the first insulating layer, and a first via penetrating the first insulating layer and connecting the first wiring and the second wiring to each other;
preparing a second substrate, the second substrate comprising a second insulating layer, a third wiring provided on a first surface of the second insulating layer, a fourth wiring provided on a second surface of the second insulating layer, and a second via penetrating the second insulating layer and connecting the third wiring and the fourth wiring to each other;
preparing a third substrate, the third substrate comprising a third insulating layer, a fifth wiring provided on a first surface of the third insulating layer, a sixth wiring provided on a second surface of the third insulating layer, and a third via penetrating the third insulating layer and connecting the fifth wiring and the sixth wiring to each other;
preparing a first bonding body comprising a first bonding material and a first connection via penetrating the first bonding material;
preparing a second bonding body comprising a second bonding material and a second connection via penetrating the second bonding material;
producing a first laminated substrate by laminating the first substrate and the second substrate such that the first bonding body is sandwiched therebetween;
preparing a second laminated substrate comprising the third substrate; and
producing a third laminated substrate by laminating the first laminated substrate and the second laminated substrate such that the second bonding body is sandwiched therebetween.

2. The method for manufacturing a multilayer substrate according to claim 1, further comprising:
preparing a fourth substrate, the fourth substrate comprising a fourth insulating layer, a seventh wiring provided on a first surface of the fourth insulating layer, an eighth wiring provided on a second surface of the fourth insulating layer, and a fourth via penetrating the fourth insulating layer and connecting the seventh wiring and the eighth wiring to each other; and
preparing a third bonding body comprising a third bonding material and a third connection via penetrating the third bonding material,
wherein the preparing the second laminated substrate comprises producing the second laminated substrate by laminating the third substrate and the fourth substrate such that the third bonding body is sandwiched therebetween.

3. The method for manufacturing a multilayer substrate according to claim 1,
wherein the first insulating layer, the second insulating layer, the third insulating layer, and the fourth insulating layer are insulating layers comprising a cured curable resin.

4. The method for manufacturing a multilayer substrate according to claim 1,
wherein the first insulating layer, the second insulating layer, the third insulating layer, and the fourth insulating layer are glass substrates.

5. The method for manufacturing a multilayer substrate according to claim 1,
wherein the first bonding material is an insulating layer comprising a semi-cured or uncured curable resin before producing the first laminated substrate, and
wherein the second bonding material is an insulating layer comprising a semi-cured or uncured curable resin before producing the third laminated substrate.

6. The method for manufacturing a multilayer substrate according to claim 1, wherein at least one via among the first via, the second via, and the first connection via is provided at a position in a planar direction different from other vias.

7. The method for manufacturing a multilayer substrate according to claim 1, wherein the first connection via is provided at a position in a planar direction different from the first via and the second via.

8. The method for manufacturing a multilayer substrate according to claim 1, further comprising preparing a fourth bonding body comprising a fourth bonding material and a fourth connection via penetrating the fourth bonding material,
wherein in the producing the third laminated substrate, two of the third laminated substrates are respectively produced by laminating the first laminated substrate and the second laminated substrate such that the second bonding body is sandwiched therebetween, and
wherein the method further comprises producing a fourth laminated substrate by laminating the two third laminated substrates such that the fourth bonding material is sandwiched therebetween.

9. The method for manufacturing a multilayer substrate according to claim 1, further comprising
forming an external terminal on an outermost layer of the multilayer substrate.

10. The method for manufacturing a multilayer substrate according to claim 1,
wherein the multilayer substrate is a package substrate.

11. The method for manufacturing a multilayer substrate according to claim 1, further comprising
inspecting at least one substrate among the first substrate, the second substrate, the third substrate, and the fourth substrate before lamination.

12. The method for manufacturing a multilayer substrate according to claim 11, wherein
in the preparing the first substrate, a plurality of first substrates are prepared,
in the preparing the second substrate, a plurality of second substrates are prepared,
in the producing the first laminated substrate, a plurality of first laminated substrates are produced,
each of the plurality of first substrates and each of the plurality of second substrates are large-format substrates comprising a plurality of wiring sections,
in the inspecting, each wiring section in each of the plurality of first substrates is inspected, and each wiring section in each of the plurality of second substrates is inspected, and
in the producing the first laminated substrate, a combination of each substrate of the plurality of first substrates and each substrate of the plurality of second substrates is selected based on an inspection result in the inspecting.

13. The method for manufacturing a multilayer substrate according to claim 12,
wherein in the producing the first laminated substrate, the selection is performed such that respective wiring sections determined to be non-defective products in the inspecting are superimposed on each other.

14. A semiconductor device, comprising:
a package substrate manufactured by the method for manufacturing a multilayer substrate according to claim 1; and
a semiconductor element mounted on the package substrate.
